(19) United States
(12) Patent Application Publication
(10) Pub. No.: US 2026/0178807 A1
(43) Pub. Date: Jun. 25, 2026

(54) HYBRID TESTING METHOD, ESPECIALLY FOR A DRIVE TRAIN OF WIND POWER PLANTS

(71) Applicant: Fraunhofer-Gesellschaft zur Förderung der Angewandten Forschung E.V., München (DE)

(72) Inventors: Paul FEJA, Bremerhaven (DE); Hans KYLING, Bremerhaven (DE); Muhammad Omer SIDDIQUI, Bremerhaven (DE); Jan WENSKE, Bremerhaven (DE)

(21) Appl. No.: 19/125,831

(22) PCT Filed: Nov. 1, 2023
(86) PCT No.: PCT/EP2023/080462

§ 371 Date: Apr. 30, 2025

(30) Foreign Application Priority Data
Nov. 1, 2022 (DE) 10 2022 211 558.9

(51) Int. Cl. G06F 30/33

(52) U.S. Cl. CPC G06F 30/33; G01N 2203/024

(57) ABSTRACT

A test procedure to determine the behavior of drive train of wind turbines under predefined loads is provided. A test stand with a test specimen to be tested is provided. The test stand has a maximum applicable load that can be applied to the test specimen. A full load is predefined for the test specimen. The full load of the test specimen is greater than the maximum applicable load of the test stand. The test specimen is subjected to a part load stress that is smaller than the test specimen's full load stress and smaller than or equal to the maximum applicable load of the test stand. Based on the results from the part load test, a simulation model is validated to test the test specimen. The validated simulation model is used to simulate the test specimen's stress tests under full load and/or overload.

The present disclosure relates to a test procedure to determine the behaviour of a test specimen, in particular a drive train of wind turbines.

The requirements for test stands, in particular for mechanical drive systems, especially for wind turbines (WTG), are growing with the increasing sizes of the test specimens. Many test stands currently available for drive trains are already too small and/or inefficient to test the requirements of modern wind turbines.

In the prior art, ever-expanding testing requirements regarding performance and/or applicable loads are met by building larger test stands, for example to test a wind turbine nacelle or a wind turbine drive train. However, putting ever larger test stands into place is associated with disproportionately increasing costs and effort. Consequently, when it comes to product development in line with the V-model, i.e. validation at different development stages during product development, widespread validation is difficult to implement at the level of the ‘powertrain’ system, because many existing test facilities do not yet offer the required test capacity for the entire specified operating range (idling, part load, full load, overload) for current and future drive train proto-types.

The present invention is therefore based on the object of proposing an alternative testing method. This object is achieved by a testing method according to claim 1. The method's advantageous further developments are set forth in the dependent claims and the following description. Examplary embodiments of the method according to the invention are explained in more detail in the description of the figures.

The proposed hybrid testing method is used to determine the behaviour of a test specimen, particularly a drive train of wind turbines, under predefined loads. The testing method comprises the following steps
I. Providing a test stand with a test specimen to be tested, the test stand having a maximum applicable load that can be applied by the test specimen on the test stand, a full load being predefined for the test specimen, the test specimen's full load being greater than the test stand's maximum applicable load,
II. operating the test stand to perform a mechanical part-load stress test on the test specimen, wherein the test specimen is subjected to a part-load stress that is lower than the test specimen's full-load stress and lower than or equal to the test stand's maximum applicable stress,
III. providing a simulation model to test the test specimen,
IV. validating the simulation model using the results of the part-load stress test in step II,
V. simulating a stress test on the test specimen under full load and/or overload in the validated simulation model.

The maximum applicable load that can be applied to the test specimen at the test stand can therefore be lower than the test specimen's full load. For example, a test stand used to test the test specimen can be significantly smaller than a test stand capable of applying the test specimen's full load to the test specimen. The investment costs for a test stand of this kind can be significantly lower than for a test stand capable of representing the test specimen's full load.

In this context, full load can be understood to mean the maximum load specified by the manufacturer. In particular, the full load can therefore be the maximum load for which the test specimen was configured. The full load for a machine may correspond to the maximum output. Overload can be understood as a load above full load.

In particular, a load range can be simulated in step V. In particular, a lower limit of the load range may be greater than or equal to the maximum load that can be applied to the test specimen at the test stand. The load region's upper limit may be less than or equal to the test specimen's full load and/or less than or equal to a test specimen's defined overload. A simulation of the load range can consist of repetitions of individual load cases in the corresponding load region performed in succession and/or simultaneously.

Conducting mechanical tests at part loads can result in lower energy requirements and/or a lower number of actual tests to be conducted, compared to testing on a test stand with higher performance. Both can lead to lower testing costs. Furthermore, the necessity to invest in larger or more powerful test stand infrastructure can be eliminated as soon as the first test requirements exceed the existing test stand capacities. Existing smaller test stands can continue to be used to test a test specimen with a higher operating power or load requirement. The operators of the existing test stands usually have validated simulation models of the test stands, which are based on data from several audit campaigns. Furthermore, it can be assumed that the existing test stands are generally more reliable (numerous faults have already been rectified) and operate more efficiently than newly commissioned test stands. Furthermore, the proposed method can be used to generate a validated simulation model that can also be used for other applications. Another advantage of the method may be that validated virtual models (in any number) can be used to test several test scenarios via parallelisation. This can lead to time and cost savings, whereas in a physical test standram, usually only one test can be carried out at any one time.

The numbering of the steps can indicate the order in which they should be performed, for example in ascending order. The implementation may, however, also differ from the ascending order. The steps can be carried out in the order I, II, III, IV, V, for example. Alternatively, the steps can be performed in the order I, III, II, IV, V or in the order III, I, II, IV, V. Steps I and III can be carried out simultaneously. Step I can be carried out before step Il is carried out. Step IV can especially be performed after Step IV. Step IV can especially be performed after Step II.

In one embodiment, the test stand applies the maximum applicable load to the test specimen in step II. This can be advantageous, for example, because a load case is mechanically tested that is comparatively close to the simulated load test of step V. In particular, in the event that the test specimen's behaviour is non-linear under increasing load, it is possible to improve the quality of the simulation model if a validation of the simulation model in step IV can be performed with load cases that are comparatively close to the simulated load case.

In one embodiment, step IV may include simulating in the simulation model a stress on the test specimen using the same part load as in the part-load stress test of step II. The results of the part-load stress test from step II and the results of the part-load simulation can be compared.

In one embodiment, the simulation model can be customised in step IV. In particular, an adjustment can be made if the results of the part-load test at the test stand and the part-load simulation are not the same and/or are not within a predefined tolerance range. This can improve the quality of the simulation model and/or the simulated results. In particular, the quality of the simulation model can show how similar a test simulated with the simulation model is to a test on a test stand under the same boundary conditions. The quality can be defined, for example, by a test image quality in the simulation process. The more similar the results of a simulated test are to the results of the same test on a test stand, the better the quality can be.

In one embodiment, the simulation model can be adjusted in step IV by adjusting the simulation model's parameters, especially if the physical-mathematical model remains unchanged. Additionally or alternatively, the simulation model can be adapted in step IV by adapting the physical-mathematical model to describe the system. New and/or modified parameters can be used.

In one embodiment, step II can be repeated for at least one further part load and/or at least two further part loads and/or at least three further part loads. Step II can be repeated for a variety of part loads. In particular, one part load or several part loads can be smaller than the maximum applicable load that can be applied by the test stand. The results of the repeated test(s) and/or the repeated tests can be used to validate the simulation model in step IV. This can improve the simulation model's accuracy. In particular, a wide range of tests can be used to detect non-linear behaviour in a test specimen. The quality of the results of the simulation in step V can be improved.

In one embodiment, to determine parameters for the simulation model in step IV, the results of the part load test in step II can be used as a reference to adjust the simulation model such that the measurements from the part load tests essentially correspond to the simulation results of the part-load stress test(s) in the simulation. The simulation model's accuracy can thus be increased.

In one embodiment, the maximum applicable load that can be applied by the test stand can be at least 40% and/or at least 50% and/or at least 60% and/or at least 70% and/or at least 90% of the test specimen's full load.

In this case, the test stand's maximum applicable load of at least 40% and/or at least 50% can have the advantage of sufficient data being collected at the test stand to validate the simulation model with comparative accuracy. Furthermore, test stand costs and/or test stand dimensions can be kept comparatively low.

Ranges of at least 60% and/or at least 70% of the test specimen's full load can be of higher quality in the simulation model compared to methods with lower maximum applicable loads that can be applied by the test stand. Furthermore, test stand costs and/or test stand dimensions can be kept comparatively low.

Ranges of at least 80% and/or at least 90% of the test specimen's full load can be of higher quality in the simulation model, compared to methods with lower maximum applicable loads that can be applied by the test stand. This increases, however, the test stand costs and/or test stand dimensions compared to methods with test stands that have lower applicable maximum loads.

The maximum applicable load for the test stand can, for example, be a maximum of 99% and/or a maximum of 90% and/or a maximum of 80% and/or a maximum of 70% and/or a maximum of 65% and/or a maximum of 60% of the test specimen's full load. Test stands able to apply very high maximum applicable loads, for example up to 99% and/or up to 90% of the test specimen's full load can provide very accurate results in the simulation process. Furthermore, a smaller and/or more cost-effective test stand can be used compared to a method that also includes a full-load test on the test stand. In this case, “smaller” can be understood as essentially “less powerful”. Less efficient test stands can usually also be built “smaller”. In the case of a lower maximum load, the test specimen to be tested in part load can still be integrated with the test stand, particularly in terms of geometry and physics.

Methods with test stands capable of applying very high maximum applicable loads, for example up to 80% and/or up to 70% of the test specimen's full load, can provide very accurate results in the simulation process. There are significant cost savings compared to a test stand that can test the test stand's full load. Additionally or alternatively, a comparatively small test stand can be used, which takes up correspondingly less storage space. In particular, for applications in which the demands on accuracy are not too high, it can be advantageous to use a test stand with a maximum applicable load of 65% and/or 60% of the test specimen's full load. A test stand of this kind is typically much smaller and cheaper than a test stand capable of applying higher loads.

It may be stipulated that the test specimen is to be subjected to various load tests. Steps I and/or II and/or III and/or IV and/or V can be repeated, for example, for different types of loads. In particular, steps Il and IV and V can be repeated, for example, for different types of loads, such as for a torsional moment and/or a bending moment and/or a pulling force and/or a compressive force. For each type of load, steps II and IV can be performed for one or more different part loads.

In one embodiment, step V may involve simulating a stress test on the test specimen under overload in the validated simulation model. Overload, for example, can be defined as a load in the range of 120% to 200% of full load.

The proposed hybrid testing method can be particularly suitable for testing a technical system that is subjected to loads on a test stand and/or a shaft-bearing unit of a technical machine's drive train and/or a wind turbine's drive train or a drive train's gear stage or a motor vehicle cardan shaft or a planetary gear for wind turbines or a rolling element bearing. The test specimen can be a technical system that is subjected to loads on a test stand and/or a shaft-bearing unit of a technical machine's drive train and/or a wind turbine's drive train or a drive train's gear stage and/or a motor vehicle cardan shaft and/or a planetary gear for wind turbines and/or a rolling element bearing.

The following description of the figures explains the method's exemplary embodiments in more detail according to the invention. The above-mentioned characteristics and combinations of characteristics serve only as illustrations and should not be understood as restrictive.

In the drawings:

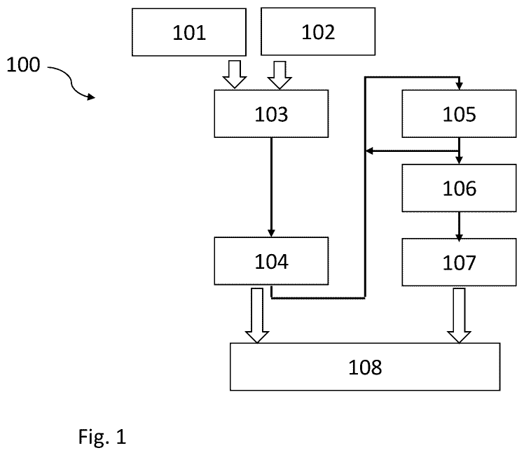

FIG. 1 a schematic flow chart illustrating a hybrid testing method to determine the behaviour of a test specimen under predefined loads,

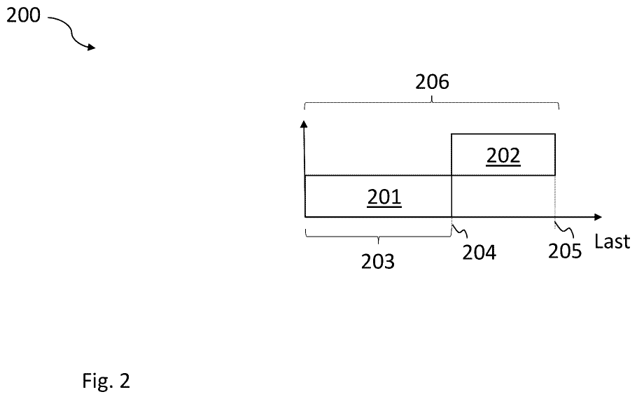

FIG. 2 a diagram showing the proportions of measurement results from physical tests and simulation results as a function of the load,

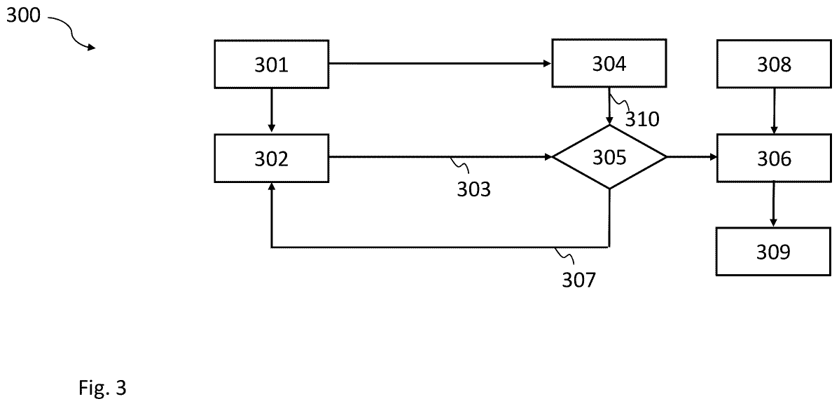

FIG. 3 an exemplary process visualisation illustrating a hybrid test method to determine a test specimen's behaviour under predefined loads,

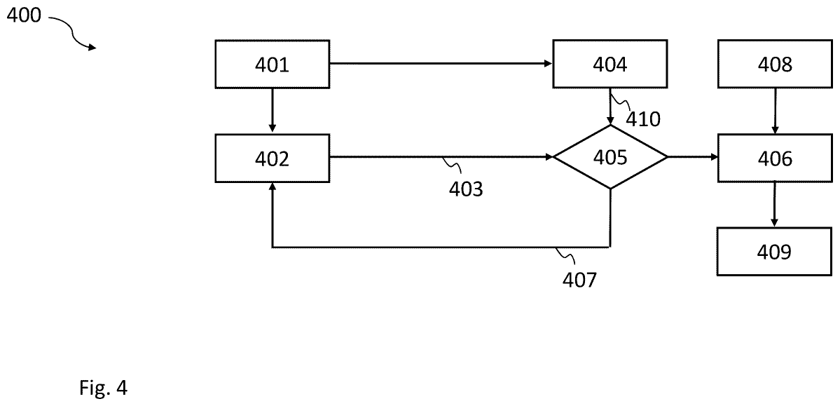

FIG. 4 an exemplary process visualisation illustrating a hybrid test method to measure a machine support's deformation of a drive train of wind turbines (WTG) under various combined loads,

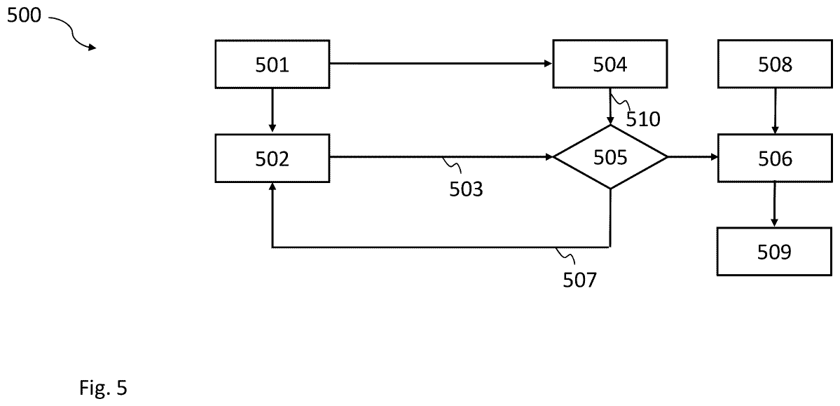

FIG. 5 an exemplary process visualisation illustrating a hybrid test method of a motor vehicle cardan shaft and

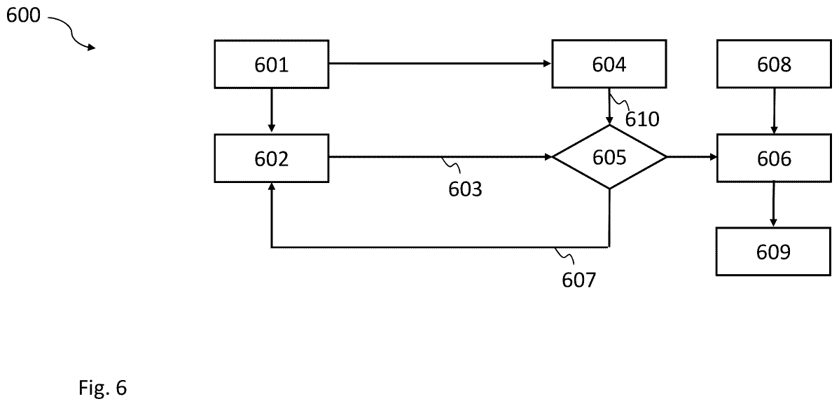

FIG. 6 an exemplary process visualisation illustrating a hybrid test method to test any deformation in the gear teeth and any displacement of the planetary carrier of a wind turbine's gearbox.

FIG. 1 shows a flow chart 100 illustrating a hybrid test procedure to determine a test specimen's behaviour under predefined loads. In a step 101, a test stand with a test specimen to be tested is provided. The test stand has a maximum applicable load that can be applied to the test specimen by the test stand. A full load is defined for the test specimen. The test specimen's full load is greater than the maximum applicable load of the test stand. For example, the maximum applicable load of the test stand is 80% of the test specimen's full load. Furthermore, in one step 102, at least one simulation model 105 is provided, which is configured to test the test specimen.

First, the test object is subjected to a mechanical load test at the test stand in step 103. The test conditions are predefined and the test stand is set up accordingly. In the mechanical load test, the test specimen is subjected to a part load. The part load is less than the test specimen's full load. The part load is either smaller than or equal to the maximum applicable load of the test stand. In the present case, the part load applied to the test specimen during the test is, for example, 80% of the test specimen's full load, thus corresponding to the maximum load of the test stand. The mechanical load test has 104 results. The results 104 are used to validate the simulation model 105 such that a validated simulation model 106 is generated. With the validated simulation model 106, a load on the test specimen under full load is simulated, resulting in simulation results 107 of a test specimen's full load.

The mechanical load test according to step 103 can optionally be repeated for further part loads of the test specimen, such that results 104 are also generated for these part loads. The simulation model 105 can be validated with the results of these further tests, which increases the accuracy of the validated simulation model 106. This leads to optimised full-load simulation results 107. With the validated simulation model, simulations can be performed over the entire specified stress and operating region. The real measurement audit campaign's results in the load range below the nominal loads can be used in two ways: on the one hand, to validate one or more realistic simulation models and, on the other, as measurement results for all (relevant) tests below the nominal loads. All further test results (full-load behaviour and cross-functional, so-called large signal performance) above the loads which can be introduced by the test equipment can be determined by the validated simulation models. The results of the mechanical load test(s) 104 and the results of the full load simulation 107 can therefore be combined to provide results 108 across the entire load region.

FIG. 2 shows a diagram 200 that displays the respective proportions of measurement results from physical tests 201 and simulation results 202 for the test procedure via the load according to FIG. 1. The range 203 represents the load range that can be applied to the test specimen by the test stand. The maximum applicable load of the test stand is the load 204. The load 205 corresponds to the test specimen's full load. By combining the results of the physical tests 201 and simulations 202, the entire load range 206 can be tested. Additionally, to analyse cross-range dynamic test scenarios, e.g. from idle to the full or overload range, the simulations can be extended back to the part-load region. While a test stand for conventional full-load tests must have a capacity of up to full load 205, the required test stand capacity 203 can be significantly reduced in the method shown, compared with the conventional full-load test. Tests can therefore be shifted to smaller, cost-efficient test stands (which, due to their principle, can also work with greater accuracy); or systems that cannot currently be tested at full load can be tested on existing test stands, even though their load requirements may exceed the test stand capacity. Using the method shown in FIG. 1, it is therefore possible to achieve equivalent results to a full-load test without the need for a test stand with maximum load introduction capacity.

FIG. 3 shows a process visualisation 300 illustrating a hybrid test procedure to determine a test specimen's behaviour under predefined loads. The process visualisation 300 shows a test procedure for a wind turbine's drive train. In particular, the system's loads, deformations and vibrations are analysed.

A simulation model 302 of a test stand with a virtual test specimen, in this case a simulation model of a wind turbine's drive train, is provided. Information 301 is fed into the simulation model 302. The information may include, for example, specified loads, such as static loads and/or torques. The loads may, for example, be part loads ranging from 50-60% of the full load 308. The simulation model can be used to analyse the behaviour of the drive train under the specified loads. The simulation provides 303 results as output. The results 303 of the simulation, for example, may contain or comprise information about the test specimen's loads and/or deflection and/or deformation and/or stresses and/or vibrations. In particular, the test specimen's behaviour, in this case the drive train, can be simulated under part load. The results concerning the virtual test specimen can be applied to the real test specimen.

Furthermore, a test stand 304 is provided, into which a real test specimen, in this case the wind turbine's drive train, is integrated for testing. The test specimen is tested on the test stand, whereby the test specimen is subjected to the same loads as the virtual test specimen during the simulation. The test provides 310 results as output. The results 310 of the test, for example, may contain or comprise information about the test specimen's loads and/or deflection and/or deformation and/or stresses and/or vibrations. In step 305, the results 310 of the test are compared with the results 303 of the simulation. If the results 310 of the test correspond to the results 303 of the simulation, or if the deviation is less than or equal to 5%, a further simulation 306 is carried out. If the results 310 of the test differ from the results 303 of the simulation by more than 5%, the simulation model is adjusted, in particular based on information from the test, as symbolised by the arrow 307. The simulation model 302, which may have been adapted, is used for the simulation 306. The simulation is carried out under full-load conditions 308 and provides information as a result 309 on the test specimen's behaviour, in this case the wind turbine's drive train under full-load conditions. Using the method shown in FIG. 3, it is therefore possible to achieve equivalent results to a full-load test without the need for a test stand with maximum load introduction capacity. Of course, other tolerances may also be provided for deviations, for example 0.1% or 1% or 2% or 10% or 15% or 20%.

The quality of the results obtained from the simulated tests can essentially be determined by the quality (accuracy) of the previously validated test specimen models. In the simplest case, the test specimen can consistently demonstrate linear operating and system behaviour. In this quasi “trivial” case, using the identified test specimen models and validated by part-load testing, the test specimen's behaviour in the full-load range can be simulated without any further steps. However, the systems to be tested may exhibit non-linearities. A ratio between the test specimen load and the test stand load capacity, particularly between 1.001-100, particularly 1.3-3, particularly 1.5-3 can be used for the above method. This can have the advantage that the test specimen's non-linearities can be measured comparatively well even in the part-load range during the physical test bench trials. The quality of the non-linear test specimen models derived from the test bench trials can essentially be determined by type of model, identification of the non-linearities and their parameter-dependent (operating condition-dependent, load-dependent) extrapolation into the full-load range. Proven methods can be used in the identification of nonlinear system behaviour for the parametric and non-parametric identification of system behaviour. For example, neural networks, general machine learning methods or regression and optimisation methods can be used. Optimisation techniques in conjunction with tensor calculus can be used to advantage when describing the non-linearities with multi-linear polynomials.

FIG. 4 illustrates a process visualisation 400 of a hybrid test method to measure a test specimen's deformation, in this case a drive train's machine support in wind turbines (WTG) under various combined loads.

The method is used to analyse the machine support's deformation at the gearbox support, for example to ensure that the azimuth bearing and drive are not subjected to impermissible loads due to a deformed machine support. Combined loads from rotor torques as well as bending and transverse forces were determined in advance as the load cases requiring investigation.

A simulation model 402 of the test stand with the test specimen is provided. The simulation model may already be available, for example, and may have been created during the drive train's configuration/development. In particular, the simulation model can be an FE simulation model. In this simulation model 402, FE simulations of the deformation of the machine support may already have been carried out. The simulations, for example, are not available in validated form. Due to the numerous model and material parameters assumed, the results may therefore be subject to a certain degree of uncertainty. Therefore, a test under full load should confirm/validate the design assumptions.

A full-scale test on a test stand for WTG drive trains could be carried out for this purpose, in which the loads considered critical are applied in the intended magnitude. However, test stands with the required load introduction capacity are rare and expensive. Using the method in FIG. 4, the test can also be performed on a test stand 404 that cannot fully achieve the intended loads, in this case, for example, only about 50-70% of the target load.

The test specimen is tested in real size on the “undersized” test stand 404, whereby the loads 401 do not fully correspond to the target loads due to the limitation on the test stand, but are instead scaled down according to test stand capacity. For example, the test object has a full-load torque of 12 MNm. However, the test on test stand 404 is carried out at a part load, namely a torque of 8 MNm. For example, the test specimen has a full-load bending moment of 24 MNm. However, the test on test stand 404 is carried out at a part load, namely a bending moment of 16 MNm. In other examples, the actual loads applied may be the maximum loads of the test stand; it is not mandatory to scale the target loads proportionally.

The first measurement results 410 for the desired target variable “machine frame's deformation of the machine frame” (e.g. in the x and y direction), which may be available in the example as a time series from a distance sensor (e.g. laser distance measurement), are obtained from the physical tests performed. Individual target loads below the test stand capacity may have been approached with it but, overall, the desired results under the target load from the physical tests cannot be determined.

Based on the measurement results 410 from the physical tests at part load, a new simulation model 406 that can accurately reproduce the physical test results of the relevant sensors is created and parameterised. The model 402 already developed for the design can also be used for this and fitted/adapted with the appropriate parameter corrections. In the simulation model 402 known, the same part loads 401 are set that were tested on the test stand 404 (with a bending moment of 16 MNm and a torque of 8 MNm). The results 403 of the simulation with the simulation model 402 are validated with the results from the test at the test stand 404 in step 405. The simulation model is adjusted (symbolised by arrow 407) until the results of the adjusted simulation model 402 essentially match the test results. The finalised, adapted simulation model then corresponds to the validated simulation model 406. Where necessary, for example due to coupling effects, the test stand can also be modelled in the simulation model. The validated simulation model 406 is able to output the measured variable of interest (deformation of the machine support) with significantly greater accuracy than a simulation model that has not been validated or adapted to test results. The simulation model provides accurate results up to the level of the loads introduced in the physical test, as it was optimised for these measurement results. With this part-load validated simulation model, simulations are now carried out under the desired target loads 408, which could not be approached in the physical test. Virtual tests are carried out at full load. The expected deformations 409 of the machine support under full load and/or overload can be determined with a high degree of accuracy from these simulations. Additional physical tests with the real target loads are thus avoided. In combination, the measurement results from the physical tests at part load and the virtual test results from the simulations with the part-load validated simulation model provide a level of information comparable to that of a physical test conducted at the target loads.

FIG. 5 illustrates a hybrid inspection method in process visualisation 500 for testing a motor vehicle cardan shaft. The method is essentially the same as that described in FIGS. 1 to 4. 504 is a test stand for examining motor vehicle drive shafts. The test stand can apply speed, torque, spring travel, and steering motion to the test specimen in accordance with the stress profiles. Parameters such as speed, torque, spring deflection, angle of deflection or joint temperature are measured and controlled. The test capacity is limited by the maximum torque and the range of spring movement (spring travel, speed, acceleration) applicable by the test stand. The test specimen, i.e. the motor vehicle cardan shaft, is tested within the capacity of the test stand 504 at part load 501. The part load 501 is particularly in the range of 50-60% of the full load 508. This is generally only one part of the test area with regard to the desired test requirements. A virtual model 502 of the test stand with the test specimen is provided. The virtual model 502 is used to perform the test virtually under part-load conditions 501. This generates results 503. The test results 510 of the test on the test stand 504 (e.g. the measured axial force and torsional backlash) are used to validate (symbolised by the arrow 507) the virtual model 502 of the test specimen (and, if applicable, the test stand) under the same part loads in step 505, thus generating a validated virtual model 506. The help of the validated virtual model 506 enables a simulation of the remaining full loads 508 and a determination of results 509 at full load. In the present case, the results 509 can, for example, arise as an axial force corresponding to the full loads and as a torsional backlash reaction.

FIG. 6 shows a hybrid test procedure in a process visualisation 600 to test any deformation in the gearbox and any displacement of the planetary carrier for wind turbines. The method is essentially the same as that described in FIGS. 1 to 5. 604 is a gearbox test stand. Gearbox test stands are an important and certification-relevant part of the development process for wind turbines that have a gearbox. The gearbox test stand 604, for example, can apply torque and/or bending and/or thrust and/or shear loads. In the present case, for example, the deformation of the gear teeth and the displacement of the so-called planetary carrier can be examined. The test stand 604 has specific limits for the maximum applicable loads. With the hybrid test method presented here, the gearbox's reaction to loads exceeding the test stand's load capacity can be determined based on the part-load validated virtual model 606 with significantly improved quality compared to a non-validated model 602. First, the gearbox is tested with part loads 601, for example with torque and/or bending loads within the capacity of the test stand 604. Test results 610 are generated in the process. These loads 601 may only be present in a partial range of the test that corresponds to the desired test requirements. During these part-load tests, any deformation of the gear teeth and the resulting planetary carrier planet are measured. For the same part loads, results 603 are determined using a virtual model 602. The measured test results 610 are used to validate 607 the virtual model 602 of the gearbox under test (and the test stand, if necessary) for the same part loads, thus generating a validated model 606. With the help of the validated virtual model 606, the remaining full loads 608 can be simulated and results 609 in the form of a gear teeth deformation and the planetary carrier's displacement corresponding to the full loads can be determined.

For example, the part load 601 can be 50-60% of the full load 608.

1-10. (canceled)

11. A hybrid test method to determine a test specimen's behavior, in particular that of a drive train of wind turbines, under predefined loads, the test method comprising the following steps:

I. providing a test stand with a test specimen to be tested, wherein the test stand has a maximum applicable load that can be applied by the test stand to the test specimen, a full load being predefined for the test specimen, the test specimen's full load being greater than the test stand's maximum applicable load,
II. operating the test stand to perform a mechanical part-load stress test on the test specimen, wherein the test specimen is subjected to a part-load stress that is lower than the test specimen's full-load stress and lower than or equal to the test stand's maximum applicable load,
III. providing a simulation model to test the test object,
IV. validating the simulation model using the results of the part-load stress test in step II,
V. simulating a stress test on the test specimen under full load and/or overload in the validated simulation model.

12. The hybrid test method according to claim 11, wherein the steps can be performed in the order I, II, III, IV, V or in the order I, III, II, IV, V or in the order III, I, II, IV, V.

13. The hybrid test method according to claim 11, wherein the test stand applies the maximum applicable load to the test specimen in step II.

14. The hybrid test method according to claim 11, wherein step IV includes simulating in the simulation model a stress on the test specimen using the same part load as in the part-load stress test of step II, and comparing the results of the part-load test of step II with the part-load simulation.

15. The hybrid test method according to claim 12, whereby the simulation model in step IV is adjusted if the results of the part-load stress test in the test stand and the part-load simulation are not equal and/or do not lie within a predefined tolerance range.

16. The hybrid test method according to claim 11, wherein step Il is repeated for at least one further part load, wherein the part load being less than the maximum applicable load of the test stand, and the results of the repeated test are used to validate the simulation model in step IV.

17. The hybrid test method according to claim 11, wherein to determine parameters for the simulation model in step IV, the results of the part load stress test in step II are used as a reference to adjust the simulation model such that the measurements from the part load tests substantially correspond to the simulation results of the part load test(s) in the simulation.

18. The hybrid test method according to claim 11, wherein the maximum applicable load of the test stand is at least 40% and/or at least 50% and/or at least 60% and/or at least 70% and/or at least 90% of the test specimen's full load and/or
the maximum applicable load of the test stand is a maximum of 99% and/or a maximum of 90% and/or a maximum of 80% and/or a maximum of 70% and/or a maximum of 65% and/or a maximum of 60% of the test specimen's full load.

19. The hybrid test method according claim 11, wherein steps II to V are repeated for different types of loads.

20. The hybrid test method according to claim 11, wherein the test specimen is a technical system that is subjected to loads on a test stand and/or the test specimen is a shaft-bearing unit of a drive train of a wind turbine of a technical machine and/or the test specimen is a drive train of a wind turbine or a gear stage of a drive train or a motor vehicle cardan shaft or a planetary gear for wind turbines or a rolling element bearing.
